(19) United States
(12) Patent Application Publication
(10) Pub. No.: US 2012/0003823 A1
(43) Pub. Date: Jan. 5, 2012

(54) METHOD FOR MANUFACTURING SEMICONDUCTOR SUBSTRATE

(75) Inventors: Makoto Sasaki, Hyogo (JP); Shin Harada, Osaka (JP); Taro Nishiguchi, Hyogo (JP); Kyoko Okita, Osaka (JP); Yasuo Namikawa, Osaka (JP)

(73) Assignee: SUMITOMO ELECTRIC INDUSTRIES, LTD., Osaka-shi (JP)

(21) Appl. No.: 13/255,314

(22) PCT Filed: Sep. 28, 2010
(86) PCT No.: PCT/JP2010/066832

§ 371 Date: Sep. 8, 2011

(30) Foreign Application Priority Data
Nov. 13, 2009 (JP) 2009-259790

(51) Int. Cl. H01L 21/20

(52) U.S. Cl. 438/478; 257/E21.09

(57) ABSTRACT

A combined substrate is prepared which has a supporting portion and first and second silicon carbide substrates. The first silicon carbide substrate has a first front-side surface and a first side surface. The second silicon carbide substrate has a second front-side surface and a second side surface. The second side surface is disposed such that a gap having an opening between the first and second front-side surfaces is formed between the first side surface and the second side surface. By introducing melted silicon from the opening into the gap, a silicon connecting portion is formed to connect the first and second side surfaces so as to close the opening. By carbonizing the silicon connecting portion, a silicon carbide connecting portion is formed.

### TECHNICAL FIELD

The present invention relates to a method for manufacturing a semiconductor substrate, in particular, a method for manufacturing a semiconductor substrate including a portion made of silicon carbide (SiC) having a single-crystal structure.

### BACKGROUND ART

In recent years, SiC substrates have been adopted as semiconductor substrates for use in manufacturing semiconductor devices. SiC has a band gap larger than that of Si (silicon), which has been used more commonly. Hence, a semiconductor device employing a SiC substrate advantageously has a large reverse breakdown voltage, low on-resistance, or has properties less likely to decrease in a high temperature environment.

In order to efficiently manufacture such semiconductor devices, the substrates need to be large in size to some extent. According to U.S. Pat. No. 7,314,520 (Patent Document 1), a SiC substrate of 76 mm (3 inches) or greater can be manufactured.

### PRIOR ART DOCUMENTS

### Patent Documents

Patent Document 1: U.S. Pat. No. 7,314,520

### SUMMARY OF THE INVENTION

### Problems to be Solved by the Invention

Industrially, the size of a SiC substrate is still limited to approximately 100 mm (4 inches). Accordingly, semiconductor devices cannot be efficiently manufactured using large substrates, disadvantageously. This disadvantage becomes particularly serious in the case of using a property of a plane other than the (0001) plane in SiC of hexagonal system. Hereinafter, this will be described.

A SiC substrate small in defect is usually manufactured by slicing a SiC ingot obtained by growth in the (0001) plane, which is less likely to cause stacking fault. Hence, a SiC substrate having a plane orientation other than the (0001) plane is obtained by slicing the ingot not in parallel with its grown surface. This makes it difficult to sufficiently secure the size of the substrate, or many portions in the ingot cannot be used effectively. For this reason, it is particularly difficult to effectively manufacture a semiconductor device that employs a plane other than the (0001) plane of SiC.

Instead of increasing the size of such a SiC substrate with difficulty, it is considered to use a semiconductor substrate having a supporting portion and a plurality of small SiC substrates disposed thereon. The size of this semiconductor substrate can be increased by increasing the number of SiC substrates as required.

However, in this semiconductor substrate, gaps are formed between adjacent SiC substrates. In the gaps, foreign matters are likely to be accumulated during a process of manufacturing a semiconductor device using the semiconductor substrate. An exemplary foreign matter is: a cleaning liquid or polishing agent used in the process of manufacturing a semiconductor device; or dust in the atmosphere. Such foreign matters result in decreased manufacturing yield, which leads to decreased efficiency of manufacturing semiconductor devices, disadvantageously.

The present invention is made in view of the foregoing problems and its object is to provide a method for manufacturing a large semiconductor substrate allowing for manufacturing of semiconductor devices with a high yield.

### Means for Solving the Problems

A method according to the present invention for manufacturing a semiconductor substrate includes the following steps.

A combined substrate is provided which has a supporting portion and first and second silicon carbide substrates. The first silicon carbide substrate has a first backside surface connected to the supporting portion, a first front-side surface opposite to the first backside surface, and a first side surface connecting the first backside surface and the first front-side surface. The second silicon carbide substrate has a second backside surface connected to the supporting portion, a second front-side surface opposite to the second backside surface, and a second side surface connecting the second backside surface and the second front-side surface. The second side surface is disposed such that a gap having an opening between the first and second front-side surfaces is formed between the first side surface and the second side surface. A silicon connecting portion is formed to connect the first and second side surfaces so as to close the opening, by introducing melted silicon from the opening to the gap. A silicon carbide connecting portion is formed to connect the first and second side surfaces so as to close the opening, by carbonizing the silicon connecting portion.

According to the present manufacturing method, the opening of the gap between the first and second silicon carbide substrates is closed. Hence, upon manufacturing a semiconductor device using the semiconductor substrate, foreign matters are not accumulated in the gap. This prevents yield from being decreased by the foreign matters, thus obtaining a semiconductor substrate allowing for manufacturing of semiconductor devices with a high yield.

In the method for manufacturing the semiconductor substrate, preferably, the step of forming the silicon carbide connecting portion includes the step of supplying the silicon connecting portion with a gas containing carbon element.

In the method for manufacturing the semiconductor substrate, the first and second front-side surfaces are exposed after the step of forming the silicon carbide connecting portion.

In the method for manufacturing the semiconductor substrate, preferably, at least a part of a substance existing on the first and second front-side surfaces is removed after the step of forming the silicon connecting portion and before the step of forming the silicon carbide connecting portion.

In the method for manufacturing the semiconductor substrate, preferably, the step of forming the silicon connecting portion includes the following steps.

A silicon layer is provided to cover the gap over the opening. The silicon layer is melted.

In the method for manufacturing the semiconductor substrate, preferably, the step of providing the silicon layer is performed using any of a chemical vapor deposition method, an evaporation method, and a sputtering method.

In the method for manufacturing the semiconductor substrate, preferably, the step of forming the silicon connecting portion includes the following steps.

Melted silicon is prepared. The opening is immersed into the melted silicon.

In the manufacturing method, preferably, the supporting portion is made of silicon carbide as with the first and second silicon carbide substrates. Accordingly, the supporting portion can be provided with properties close to those of the first and second silicon carbide substrates.

### Effects of the Invention

As apparent from the description above, the present invention can provide a method for manufacturing a large semiconductor substrate allowing for manufacturing of semiconductor devices with a high yield.

### BRIEF DESCRIPTION OF THE DRAWINGS

FIG. 1 is a plan view schematically showing a configuration of a semiconductor substrate in a first embodiment of the present invention.

FIG. 2 is a schematic cross sectional view taken along a line II-II in FIG. 1.

FIG. 3 is a plan view schematically showing a first step of a method for manufacturing the semiconductor substrate in the first embodiment of the present invention.

FIG. 4 is a schematic cross sectional view taken along a line IV-IV in FIG. 3.

FIG. 5 is a cross sectional view schematically showing a second step of the method for manufacturing the semiconductor substrate in the first embodiment of the present invention.

FIG. 6 is a partial cross sectional view schematically showing a third step of the method for manufacturing the semiconductor substrate in the first embodiment of the present invention.

FIG. 7 is a partial cross sectional view schematically showing a fourth step of the method for manufacturing the semiconductor substrate in the first embodiment of the present invention.

FIG. 8 is a partial cross sectional view schematically showing a fifth step of the method for manufacturing the semiconductor substrate in the first embodiment of the present invention.

FIG. 9 is a cross sectional view schematically showing a sixth step of the method for manufacturing the semiconductor substrate in the first embodiment of the present invention.

FIG. 10 is a cross sectional view schematically showing a first step of a method for manufacturing a semiconductor substrate in a second embodiment of the present invention.

FIG. 11 is a cross sectional view schematically showing a second step of the method for manufacturing the semiconductor substrate in the second embodiment of the present invention.

FIG. 12 is a cross sectional view schematically showing a third step of the method for manufacturing the semiconductor substrate in the second embodiment of the present invention.

FIG. 13 is a cross sectional view schematically showing a first step of a method for manufacturing a semiconductor substrate in a third embodiment of the present invention.

FIG. 14 is a cross sectional view schematically showing a second step of the method for manufacturing the semiconductor substrate in the third embodiment of the present invention.

FIG. 15 is a cross sectional view schematically showing a third step of the method for manufacturing the semiconductor substrate in the third embodiment of the present invention.

FIG. 16 is a cross sectional view schematically showing one step of a method for manufacturing a semiconductor substrate in a first variation of the third embodiment of the present invention.

FIG. 17 is a cross sectional view schematically showing one step of a method for manufacturing a semiconductor substrate in a second variation of the third embodiment of the present invention.

FIG. 18 is a cross sectional view schematically showing one step of a method for manufacturing a semiconductor substrate in a third variation of the third embodiment of the present invention.

FIG. 19 is a partial cross sectional view schematically showing a configuration of a semiconductor device in a fourth embodiment of the present invention.

FIG. 20 is a schematic flowchart showing a method for manufacturing the semiconductor device in the fourth embodiment of the present invention.

FIG. 21 is a partial cross sectional view schematically showing a first step of the method for manufacturing the semiconductor device in the fourth embodiment of the present invention.

FIG. 22 is a partial cross sectional view schematically showing a second step of the method for manufacturing the semiconductor device in the fourth embodiment of the present invention.

FIG. 23 is a partial cross sectional view schematically showing a third step of the method for manufacturing the semiconductor device in the fourth embodiment of the present invention.

FIG. 24 is a partial cross sectional view schematically showing a fourth step of the method for manufacturing the semiconductor device in the fourth embodiment of the present invention.

### MODES FOR CARRYING OUT THE INVENTION

The following describes an embodiment of the present invention with reference to figures.

### First Embodiment

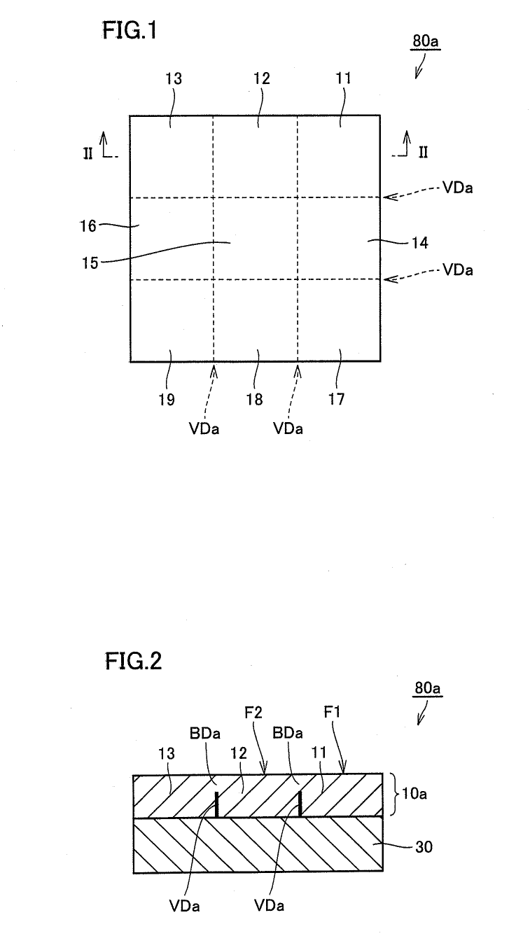

Referring to FIG. 1 and FIG. 2, a semiconductor substrate 80a of the present embodiment has a supporting portion 30 and a supported portion 10a supported by supporting portion 30. Supported portion 10a has SiC substrates 11-19 (silicon carbide substrates).

Supporting portion 30 connects the backside surfaces of SiC substrates 11-19 (surfaces opposite to the surfaces shown in FIG. 1) to one another, whereby SiC substrates 11-19 are fixed to one another. SiC substrates 11-19 respectively have exposed front-side surfaces on the same plane. For example, SiC substrates 11 and 12 respectively have first and second front-side surfaces F1, F2 (FIG. 2). Thus, semiconductor substrate 80a has a surface larger than the surface of each of SiC substrates 11-19. Hence, in the case of using semiconductor substrate 80a, semiconductor devices can be manufactured more effectively than in the case of using each of SiC substrates 11-19 solely.

Further, supporting portion 30 is made of a material having a high heat resistance, and is preferably made of a material capable of enduring 1800° C. or greater. A usable example of such a material is silicon carbide, carbon, or a refractory metal. An exemplary refractory metal usable is molybdenum, tantalum, tungsten, niobium, iridium, ruthenium, or zirconium. When silicon carbide is employed as the material of supporting portion 30 from among the materials exemplified above, supporting portion 30 has properties closer to those of SiC substrates 11-19.

In supported portion 10a, gaps VDa exist between SiC substrates 11-19. These gaps VDa are closed at their front-side surface sides (upper sides in FIG. 2) by silicon carbide connecting portions BDa. Each of silicon carbide connecting portions BDa has a portion located between first and second front-side surfaces F1, F2, whereby first and second front-side surfaces F1, F2 are connected to each other smoothly.

Next, a method for manufacturing semiconductor substrate 80a of the present embodiment will be described. For ease of description, only SiC substrates 11 and 12 of SiC substrates 11-19 may be explained, but the same explanation also applies to SiC substrates 13-19.

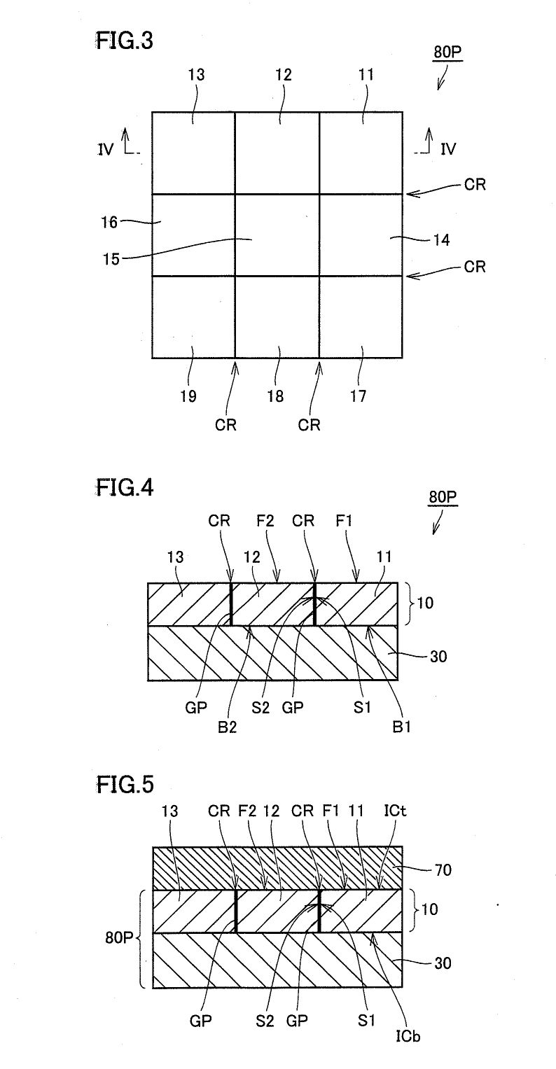

Referring to FIG. 3 and FIG. 4, a combined substrate 80P is prepared. Combined substrate 80P includes supporting portion 30 and a SiC substrate group 10.

SiC substrate group 10 includes SiC substrate 11 (first silicon carbide substrate) and SiC substrate 12 (second silicon carbide substrate). SiC substrate 11 has first backside surface B1 connected to supporting portion 30, first front-side surface F1 opposite to first backside surface B1, and a first side surface S1 connecting first backside surface B1 and first front-side surface F1. SiC substrate 12 (second silicon carbide substrate) has second backside surface B2 connected to supporting portion 30, second front-side surface F2 opposite to second backside surface B2, and a second side surface S2 connecting second backside surface B2 and second front-side surface F2. Second side surface S2 is disposed such that a gap GP having an opening CR between first and second front-side surfaces F1, F2 is formed between first side surface S1 and second side surface S2.

Referring to FIG. 5, silicon layer 70 is formed on first and second front-side surfaces F1, F2 so as to cover gap GP over opening CR. As a formation method therefor, a chemical vapor deposition method, an evaporation method, or a sputtering method can be used, for example.

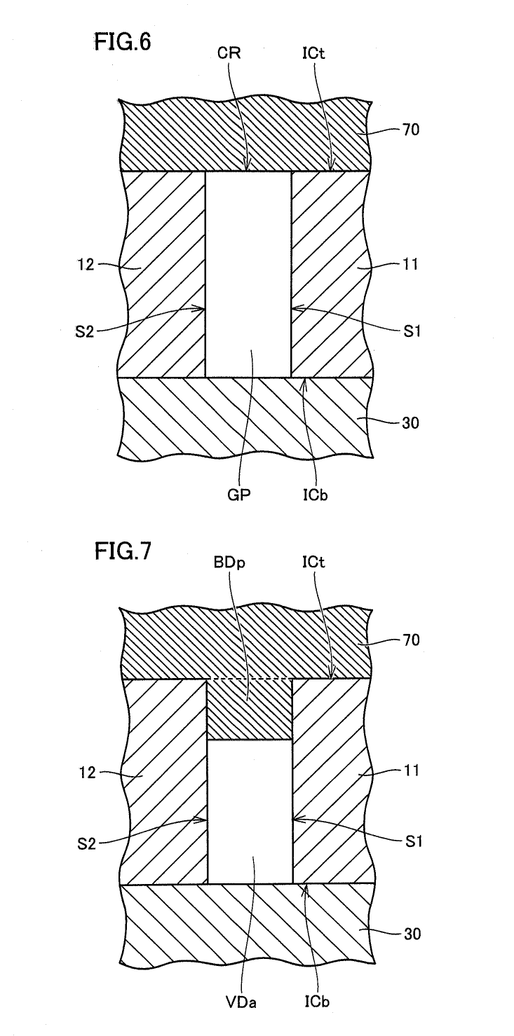

Referring to FIG. 6, silicon layer 70 is heated to a temperature equal to or higher than its melting point, and is accordingly melted. Accordingly, the silicon thus melted is introduced into gap GP via opening CR. Preferably, the temperature of this heating is 2200° C. or smaller.

Further, referring to FIG. 7, as a result of the introduction of the melted silicon, silicon connecting portion BDp (FIG. 7) is formed to close opening CR of gap GP (FIG. 6) and accordingly connect first and second side surfaces S1, S2 to each other.

Then, silicon connecting portion BDp is heated to a temperature of not less than 1700° C. and not more than 2500° C. Accordingly, at least a portion of silicon connecting portion BDp is carbonized.

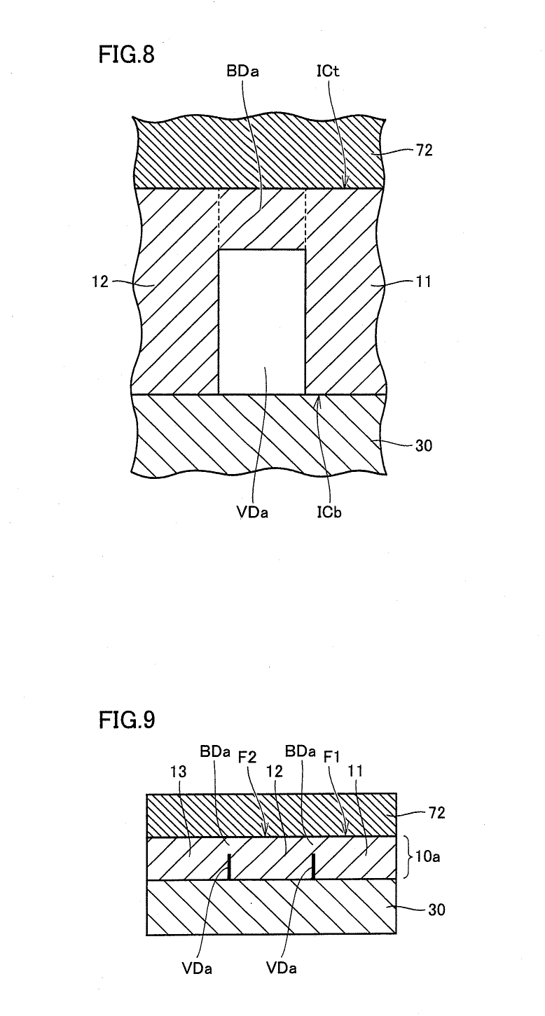

Referring to FIG. 8, as a result of the carbonization, silicon carbide connecting portion BDa made of silicon carbide is formed to connect first and second side surfaces S1, S2 so as to close opening CR. Carbon element in each of SiC substrates 11 and 12 contributes to this carbonization.

Further, at the same time as the carbonization, at least a portion of silicon layer 70 may be carbonized to form a carbonized layer 72.

Preferably, in this carbonizing step, silicon layer 70 and silicon connecting portion BDp (FIG. 7) are supplied with a gas containing carbon element. This carbon element contributes to the carbonization. An exemplary gas usable is propane or acetylene.

Referring to FIG. 9, carbonized layer 72 is removed to expose first and second front-side surface F1, F2. As a removal method therefor, a chemical-mechanical polishing method can be used, for example. In this way, semiconductor substrate 80a (FIG. 2) is obtained.

According to the present embodiment, as shown in FIG. 2, SiC substrates 11 and 12 are combined as one semiconductor substrate 80a through supporting portion 30. Semiconductor substrate 80a includes respective first and second front-side surfaces F1, F2 of the SiC substrates, as its substrate surface on which a semiconductor device such as a transistor is to be formed. In other words, semiconductor substrate 80a has a larger substrate surface than in the case where any of SiC substrates 11 and 12 is solely used. Thus, semiconductor substrate 80a allows semiconductor devices to be manufactured efficiently.

Further, in the process of manufacturing semiconductor substrate 80a, opening CR between first and second front-side surfaces F1, F2 of combined substrate 80P (FIG. 4) is closed by silicon carbide connecting portion BDa (FIG. 2). Accordingly, first and second front-side surfaces F1, F2 are connected to each other smoothly. As such, in the process of manufacturing a semiconductor device using semiconductor substrate 80a, foreign matters, which would cause decreased yield, are less likely to be accumulated between first and second front-side surfaces F1, F2. Thus, the use of semiconductor substrate 80a allows semiconductor devices to be manufactured with a high yield.

Further, silicon carbide connecting portion BDa is made of silicon carbide and therefore has a heat resistance as high as those of SiC substrates 11 and 12. Accordingly, silicon carbide connecting portion BDa is capable of enduring a temperature normally applied in a process of manufacturing semiconductor devices using SiC substrates.

It should be noted that preferably, silicon layer 70 (FIG. 5) has a thickness of more than 0.1 μm and less than 1 mm. If the thickness thereof is 0.1 μm or less, an amount of silicon introduced into gap GP is too small, which may lead to too small thickness of silicon connecting portion BDp (FIG. 7) or discontinuity of silicon connecting portion BDp in opening CR. On the other hand, if the thickness of silicon layer 70 is 1 mm or greater, first and second front-side surface F1, F2 are likely to be rough due to the reaction with silicon layer 70 in the carbonizing step, or it may take too a long time to remove carbonized layer 72 (FIG. 8).

Further, after the formation of silicon connecting portion BDp (FIG. 7), at least a portion of silicon layer 70 on first and second front-side surface F1, F2 may be removed, and then the carbonizing step may be performed. Accordingly, while securely forming silicon connecting portion BDp by forming sufficiently thick silicon layer 70, first and second front-side surfaces F1, F2 can be prevented from being rough due to the reaction with silicon layer 70 in the carbonizing step. As a method for removing silicon layer 70, the etching method or the chemical-mechanical polishing method can be used.

Further, in the manufacturing method described above, carbonized layer 72 is removed. However, in the case where carbonized layer 72 can be used for manufacturing of a semiconductor device, carbonized layer 72 may be remained.

### Second Embodiment

Also in a method for manufacturing a semiconductor substrate in the present embodiment, combined substrate 80P (FIG. 3, FIG. 4) is prepared as with the first embodiment. For ease of description, only SiC substrates 11 and 12 of SiC substrates 11-19 provided in combined substrate 80P may be explained, but the same explanation also applies to SiC substrates 13-19.

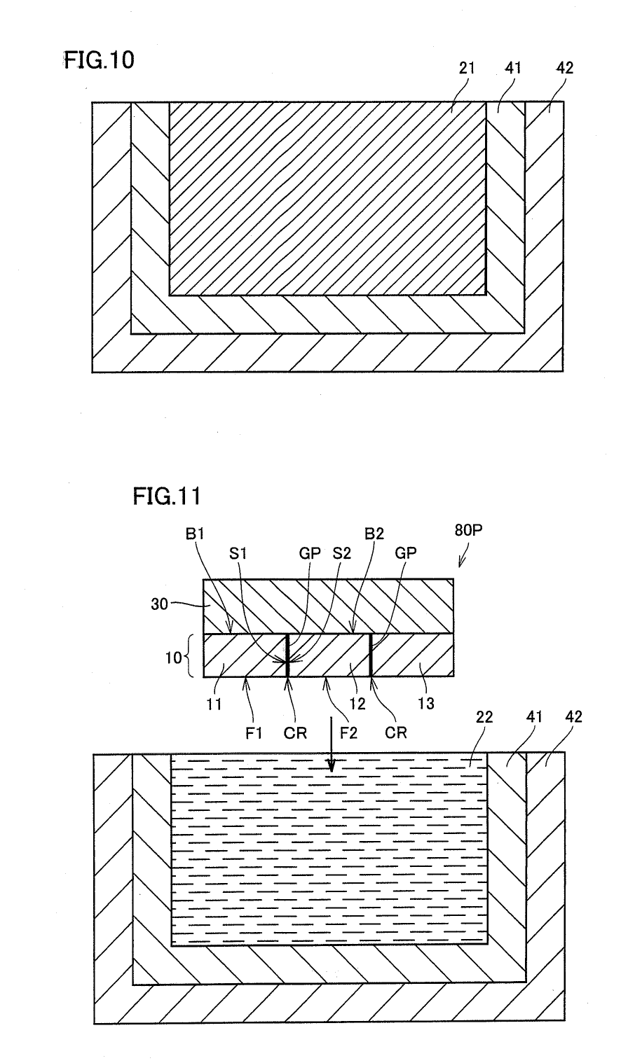

Referring to FIG. 10, in a processing chamber (not shown), a Si material 21 formed of solid Si is contained in a crucible 41. Further, crucible 41 is accommodated in a source material heating member 42. Preferably, atmosphere in the processing chamber is an inert gas.

Further, as source material heating member 42, any heating member can be used as long as it is capable of heating a target object. For example, the heating member can be of resistive heating type employing a graphite heater, or of inductive heating type.

Next, Si material 21 is heated by source material heating member 42 to reach or exceed the melting point of Si, thereby melting Si material 21.

Referring to FIG. 11, by the melting, a Si melt 22 is formed. As indicated by an arrow in the figure, opening CR of combined substrate 80P is immersed in Si melt 22.

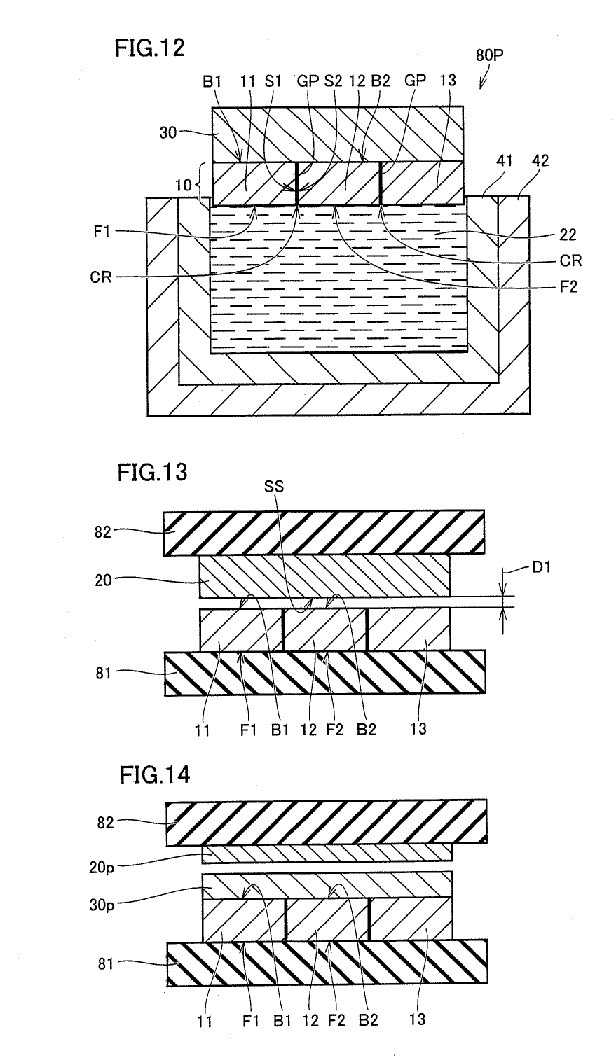

Referring to FIG. 12 mainly, as a result of the immersion, melt 22 comes into contact with front-side surfaces F1 and F2 of combined substrate 80P and is introduced into gap GP from opening CR. Accordingly, a structure similar to silicon layer 70 and silicon connecting portion BDp (FIG. 7) is formed. Then, combined substrate 80P is pulled up from melt 22 (FIG. 12).

Thereafter, preferably, at least a portion of silicon layer 70 existing on first and second front-side surfaces F1, F2 (FIG. 7) is removed. More preferably, the thickness of silicon layer 70 is adapted to be 100 μm or less. Accordingly, first and second front-side surface F1, F2 can be prevented from being rough due to the reaction with silicon layer 70 in the carbonizing step. As a method for removing silicon layer 70, the etching method or the chemical-mechanical polishing method can be used, for example.

Next, a carbonizing step similar to that in the first embodiment is performed, thereby obtaining a semiconductor substrate of the present embodiment, which is similar to semiconductor substrate 80a (FIG. 2).

According to the present embodiment, silicon connecting portion BDp (FIG. 7) can be formed by the melt growth method, unlike the first embodiment.

### Third Embodiment

In the present embodiment, the following fully describes a particular case where supporting portion 30 is made of silicon carbide in the method for manufacturing combined substrate 80P (FIG. 3, FIG. 4) used in the first embodiment. For ease of description, only SiC substrates 11 and 12 of SiC substrates 11-19 (FIG. 3, FIG. 4) may be explained, but the same explanation also applies to SiC substrates 13-19.

Referring to FIG. 13, SiC substrates 11 and 12 are prepared each of which has a single-crystal structure. Specifically, for example, SiC substrates 11 and 12 are prepared by cutting, along the (03-38) plane, a SiC ingot grown in the (0001) plane in the hexagonal system. Preferably, each of backside surfaces B1 and B2 has a roughness Ra of not more than 100 μm.

Next, SiC substrates 11 and 12 are placed on a first heating member 81 in the processing chamber with each of backside surfaces B1 and B2 being exposed in one direction (upward in FIG. 13). Namely, when viewed in a plan view, SiC substrates 11 and 12 are arranged side by side.

Preferably, this arrangement is accomplished by disposing backside surfaces B1 and B2 on the same flat plane or by disposing first and second front-side surfaces F1, F2 on the same flat plane.

Further, a minimum space between SiC substrates 11 and 12 (minimum space in a lateral direction in FIG. 13) is preferably 5 mm or smaller, more preferably, 1 mm or smaller, and further preferably 100 μm or smaller, and particularly preferably 10 μm or smaller. Specifically, for example, the substrates, which have the same rectangular shape, are arranged in the form of a matrix with a space of 1 mm or smaller therebetween.

Next, supporting portion 30 (FIG. 2) is formed to connect backside surfaces B1 and B2 to each other in the following manner.

First, each of backside surfaces B1 and B2 exposed in the one direction (upward in FIG. 13) and a surface SS of a solid source material 20 disposed in the one direction (upward in FIG. 13) relative to backside surfaces B1 and B2 are arranged face to face with a space D1 provided therebetween. Preferably, space D1 has an average value of not less than 1 μm and not more than 1 cm.

Solid source material 20 is made of SiC, and is preferably a piece of solid matter of silicon carbide, specifically, a SiC wafer, for example. Solid source material 20 is not particularly limited in crystal structure of SiC. Further, surface SS of solid source material 20 preferably has a roughness Ra of 1 mm or smaller.

In order to provide space D1 (FIG. 13) more securely, there may be used spacers 83 (FIG. 16) each having a height corresponding to space D1. This method is particularly effective when the average value of space D1 is approximately 100 μm.

Next, SiC substrates 11 and 12 are heated by first heating member 81 to a predetermined substrate temperature. On the other hand, solid source material 20 is heated by a second heating member 82 to a predetermined source material temperature. When solid source material 20 is thus heated to the source material temperature, SiC is sublimated at surface SS of the solid source material to generate a sublimate, i.e., gas. The gas thus generated is supplied onto backside surfaces B1 and B2 in the one direction (from upward in FIG. 13).

Preferably, the substrate temperature is set lower than the source material temperature. More preferably, a difference between the substrate temperature and the source material temperature is set to cause a temperature gradient of not less than 0.1° C./mm and not more than 100° C./mm in the direction of thickness in each of SiC substrates 11, 12 and solid source material 20 (in the vertical direction in FIG. 13). More preferably, the substrate temperature is not less than 1800° C. and not more than 2500° C.

Referring to FIG. 14, the gas supplied as described above is solidified and accordingly recrystallized on each of backside surfaces B1 and B2. In this way, a supporting portion 30p is formed to connect backside surfaces B1 and B2 to each other. Further, solid source material 20 (FIG. 13) is consumed and is reduced in size to be a solid source material 20p.

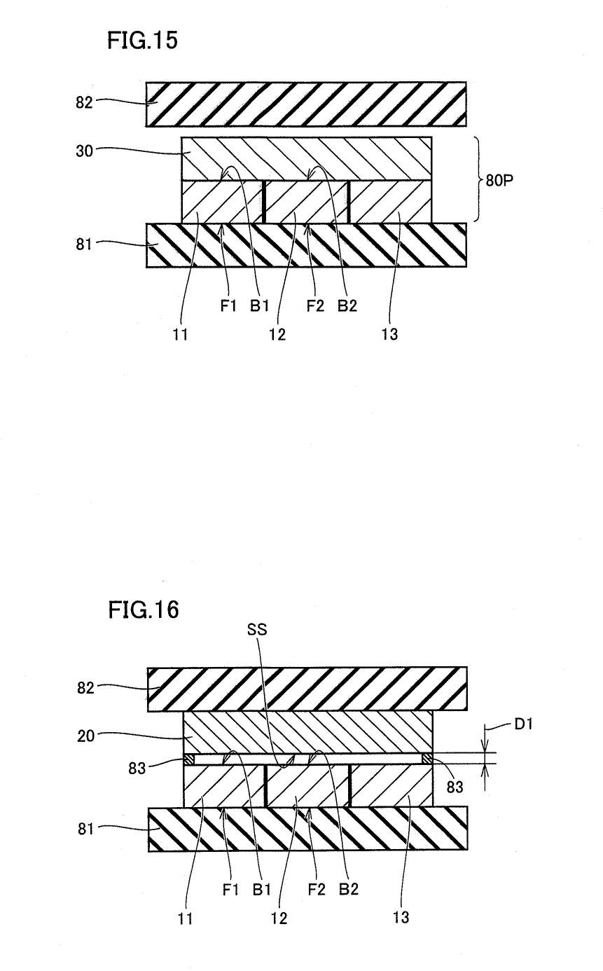

Referring to FIG. 15 mainly, as the sublimation develops, solid source material 20p (FIG. 14) is run out. In this way, supporting portion 30 is formed to connect backside surfaces B1 and B2 to each other.

Upon the formation of supporting layer 30, the atmosphere in the processing chamber is preferably obtained by reducing the pressure of the atmospheric air. The pressure of atmosphere is preferably higher than 10⁻¹ Pa and lower than 10⁴ Pa.

The atmosphere described above may be an inert gas atmosphere. An exemplary inert gas usable is a noble gas such as He or Ar; a nitrogen gas; or a mixed gas of the noble gas and nitrogen gas. When using the mixed gas, a ratio of the nitrogen gas is, for example, 60%. Further, the pressure in the processing chamber is preferably 50 kPa or smaller, and is more preferably 10 kPa or smaller.

Further, supporting portion 30 preferably has a single-crystal structure. More preferably, supporting portion 30 on backside surface B1 has a crystal plane inclined by 10° or smaller relative to the crystal plane of backside surface B1, and supporting portion 30 on backside surface B2 has a crystal plane inclined by 10° relative to the crystal plane of backside surface B2. These angular relations can be readily realized by expitaxially growing supporting portion 30 on backside surfaces B1 and B2.

The crystal structure of each of SiC substrates 11, 12 is preferably of hexagonal system, and is more preferably 4H—SiC or 6H—SiC. Moreover, it is preferable that SiC substrates 11, 12 and supporting portion 30 be made of SiC single crystal having the same crystal structure.

Further, the concentration in each of SiC substrates 11 and 12 is preferably different from the impurity concentration of supporting portion 30. More preferably, supporting portion 30 has an impurity concentration higher than that of each of SiC substrates 11 and 12. It should be noted that the impurity concentration of each of SiC substrates 11, 12 is, for example, not less than 5×10¹⁶ cm⁻³ and not more than 5×10¹⁹ cm⁻³. In addition, the impurity concentration of supporting portion 30 is, for example, not less than 5×10¹⁶ cm⁻³ and not more than 5×10²¹ cm⁻³. As the impurity, nitrogen or phosphorus can be used, for example.

Further, preferably, first front-side surface F1 has an off angle of 50° or greater and 65° or smaller relative to the {0001} plane of SiC substrate 11 and second front-side surface F2 has an off angle of 50° or greater and 65° or smaller relative to the {0001} plane of the SiC substrate.

More preferably, the off orientation of first front-side surface F1 forms an angle of 5° or smaller relative to the <1-100> direction of SiC substrate 11, and the off orientation of second front-side surface F2 forms an angle of 5° or smaller with the <1-100> direction of substrate 12.

Further, first front-side surface F1 preferably has an off angle of not less than −3° and not more than 5° relative to the {03-38} plane in the <1-100> direction of SiC substrate 11, and second front-side surface F2 preferably has an off angle of not less than −3° and not more than 5° relative to the {03-38} plane in the <1-100> direction of SiC substrate 12.

It should be noted that the “off angle of first front-side surface F1 relative to the {03-38} plane in the <1-100> direction” refers to an angle formed by an orthogonal projection of a normal line of first front-side surface F1 to a projection plane defined by the <1-100> direction and the <0001> direction, and a normal line of the {03-38} plane. The sign of positive value corresponds to a case where the orthogonal projection approaches in parallel with the <1-100> direction whereas the sign of negative value corresponds to a case where the orthogonal projection approaches in parallel with the <0001> direction. This is similar in the “off angle of second front-side surface F2 relative to the {03-38} plane in the <1-100> direction”.

Further, the off orientation of first front-side surface F1 forms an angle of 5° or smaller with the <11-20> direction of substrate 11. The off orientation of second front-side surface F2 forms an angle of 5° or smaller with the <11-20> direction of substrate 12.

According to the present embodiment, since supporting portion 30 formed on backside surfaces B1 and B2 is also made of SiC as with SiC substrates 11 and 12, physical properties of the SiC substrates and supporting portion 30 are close to one another. Accordingly, warpage or cracks of combined substrate 80P (FIG. 3, FIG. 4) or semiconductor substrate 80a (FIG. 1, FIG. 2) resulting from a difference in physical property therebetween can be suppressed.

Further, utilization of the sublimation method allows supporting portion 30 to be formed fast with high quality. When the sublimation method thus utilized is a close-spaced sublimation method, supporting portion 30 can be formed more uniformly.

Further, when the average value of space D1 (FIG. 13) between each of backside surfaces B1 and B2 and the surface of solid source material 20 is 1 cm or smaller, distribution in film thickness of supporting portion 30 can be reduced. So far as the average value of space D1 is 1 μm or greater, a space for sublimation of SiC can be sufficiently secured.

Meanwhile, in the step of forming supporting portion 30, the temperatures of SiC substrates 11 and 12 are set lower than that of solid source material 20 (FIG. 13). This allows the sublimated SiC to be efficiently solidified on SiC substrates 11 and 12.

Further, the step of placing SiC substrates 11 and 12 is preferably performed to allow the minimum space between SiC substrates 11 and 12 to be 1 mm or smaller. Accordingly, supporting portion 30 can be formed to connect backside surface B1 of SiC substrate 11 and backside surface B2 of SiC substrate 12 to each other more securely.

Further, supporting portion 30 preferably has a single-crystal structure. Accordingly, supporting portion 30 has physical properties close to the physical properties of SiC substrates 11 and 12 each having a single-crystal structure.

More preferably, supporting portion 30 on backside surface B1 has a crystal plane inclined by 10° or smaller relative to that of backside surface B1, Further, supporting portion 30 on backside surface B2 has a crystal plane inclined by 10° or smaller relative to that of backside surface B2. Accordingly, supporting portion 30 has anisotropy close to that of each of SiC substrates 11 and 12.

Further, preferably, each of SiC substrates 11 and 12 has an impurity concentration different from that of supporting portion 30. Accordingly, there can be obtained semiconductor substrate 80a (FIG. 2) having a structure of two layers with different impurity concentrations.

Furthermore, the impurity concentration in supporting portion 30 is preferably higher than the impurity concentration in each of SiC substrates 11 and 12. This allows the resistivity of supporting portion 30 to be smaller than those of SiC substrates 11 and 12. Accordingly, there can be obtained semiconductor substrate 80a suitable for manufacturing of a semiconductor device in which a current flows in the thickness direction of supporting portion 30, i.e., a semiconductor device of vertical type.

Meanwhile, preferably, first front-side surface F1 has an off angle of not less than 50° and not more than 65° relative to the {0001} plane of SiC substrate 11 and second front-side surface F2 has an off angle of not less than 50° and not more than 65° relative to the {0001} plane of SiC substrate 12. This achieves further improved channel mobility in each of first and second front-side surfaces F1, F2, as compared with a case where each of first and second front-side surfaces F1, F2 corresponds to the {0001} plane.

More preferably, the off orientation of first front-side surface F1 forms an angle of not more than 5° with the <1-100> direction of SiC substrate 11, and the off orientation of second front-side surface F2 forms an angle of not more than 5° with the <1-100> direction of SiC substrate 12. This achieves further improved channel mobility in each of first and second front-side surfaces F1, F2.

Further, first front-side surface F1 preferably has an off angle of not less than −3° and not more than 5° relative to the {03-38} plane in the <1-100> direction of SiC substrate 11, and second front-side surface F2 preferably has an off angle of not less than −3° and not more than 5° relative to the {03-38} plane in the <1-100> direction of SiC substrate 12. This achieves further improved channel mobility in each of first and second front-side surfaces F1, F2.

Further, preferably, the off orientation of first front-side surface F1 forms an angle of not more than 5° with the <11-20> direction of SiC substrate 11, and the off orientation of second front-side surface F2 forms an angle of not more than 5° with the <11-20> direction of SiC substrate 12. This achieves further improved channel mobility in each of first and second front-side surfaces F1, F2, as compared with a case where each of first and second front-side surfaces F1, F2 corresponds to the {0001} plane.

In the description above, the SiC wafer is exemplified as solid source material 20, but solid source material 20 is not limited to this and may be a SiC powder or a SiC sintered compact, for example.

Further, as first and second heating members 81, 82, any heating members can be used as long as they are capable of heating a target object. For example, the heating members can be of resistive heating type employing a graphite heater, or of inductive heating type.

Meanwhile, in FIG. 13, the space is provided between each of backside surfaces B1 and B2 and surface SS of solid source material 20 to extend therealong entirely. However, a space may be provided between each of backside surfaces B1 and B2 and surface SS of solid source material 20 while each of backside surface B1 and B2 and surface SS of solid source material 20 are partially in contact with each other. The following describes two variations corresponding to this case.

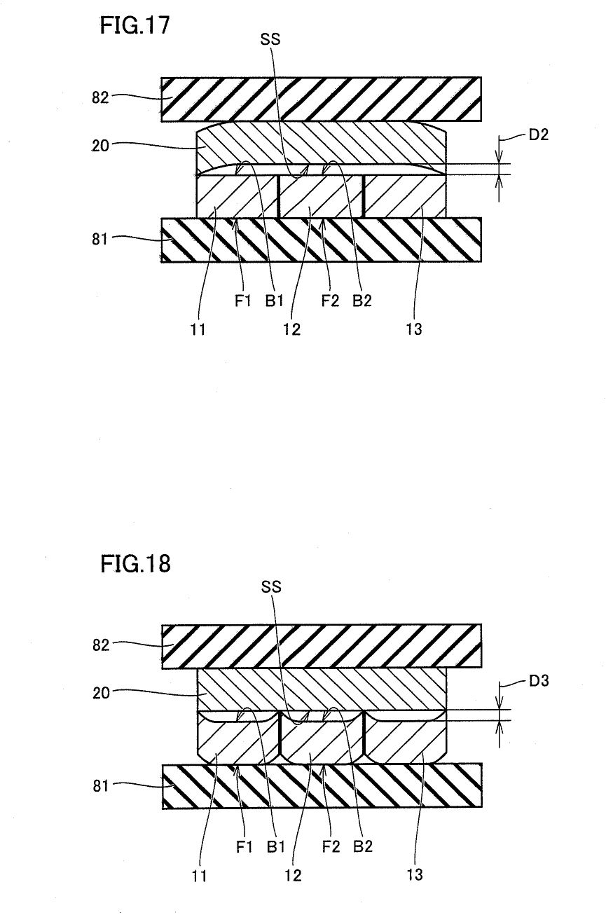

Referring to FIG. 17, in this variation, the space is secured by warpage of the SiC wafer serving as solid source material 20. More specifically, in the present variation, there is provided a space D2 that is locally zero but surely has an average value exceeding zero. Further, as with the average value of space D1, space D2 preferably has an average value of not less than 1 μm and not more than 1 cm.

Referring to FIG. 18, in this variation, the space is secured by warpage of each of SiC substrates 11-13. More specifically, in the present variation, there is provided a space D3 that is locally zero but surely has an average value exceeding zero. Further, as with the average value of space D1, space D3 preferably has an average value of not less than 1 μm and not more than 1 cm.

In addition, the space may be secured by combination of the respective methods shown in FIG. 17 and FIG. 18, i.e., by both the warpage of the SiC wafer serving as solid source material 20 and the warpage of each of SiC substrates 11-13.

Each of the above-described methods shown in FIG. 17 and FIG. 18 or the combination of these methods is particularly effective when the average value of the space is not more than 100 μm.

### Fourth Embodiment

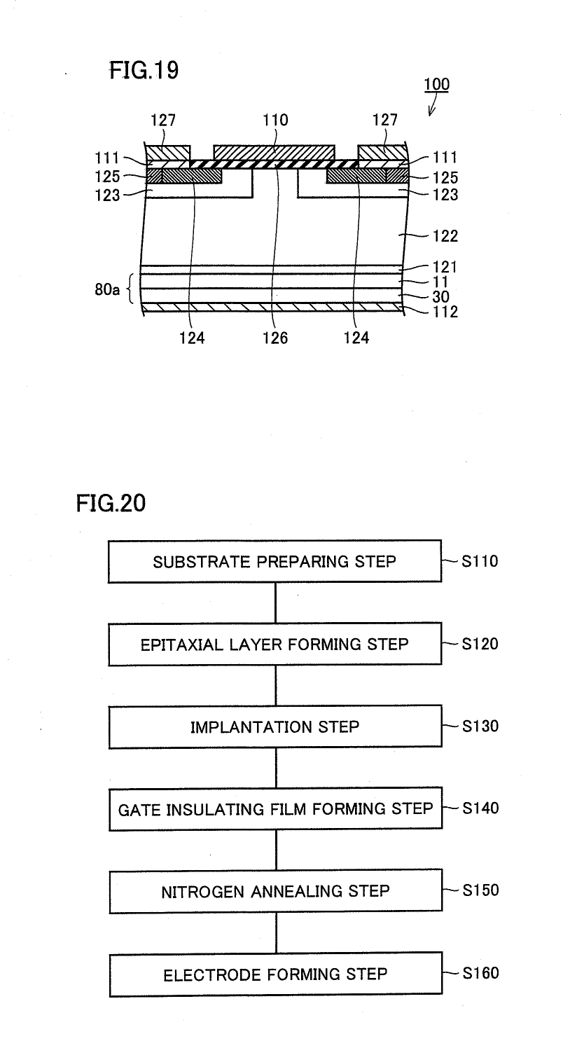

Referring to FIG. 19, a semiconductor device 100 of the present embodiment is a DiMOSFET (Double Implanted Metal Oxide Semiconductor Field Effect Transistor) of vertical type, and has a semiconductor substrate 80a, a buffer layer 121, a reverse breakdown voltage holding layer 122, p regions 123, n⁺ regions 124, p⁺ regions 125, an oxide film 126, source electrodes 111, upper source electrodes 127, a gate electrode 110, and a drain electrode 112.

In the present embodiment, semiconductor substrate 80a has n type conductivity, and has supporting portion 30 and SiC substrate 11 as described in the first embodiment. Drain electrode 112 is provided on supporting portion 30 to interpose supporting portion 30 between drain electrode 112 and SiC substrate 11. Buffer layer 121 is provided on SiC substrate 11 to interpose SiC substrate 11 between buffer layer 121 and supporting portion 30.

Buffer layer 121 has n type conductivity, and has a thickness of, for example, 0.5 μm. Further, impurity with n type conductivity in buffer layer 121 has a concentration of, for example, 5×10¹⁷ cm⁻³.

Reverse breakdown voltage holding layer 122 is formed on buffer layer 121, and is made of silicon carbide with n type conductivity. For example, reverse breakdown voltage holding layer 122 has a thickness of 10 μm, and includes a conductive impurity of n type at a concentration of 5×10¹⁵ cm⁻³.

Reverse breakdown voltage holding layer 122 has a surface in which the plurality of p regions 123 of p type conductivity are formed with spaces therebetween. In each of p regions 123, an n⁺ region 124 is formed at the surface layer of p region 123. Further, at a location adjacent to n⁺ region 124, a p⁺ region 125 is formed. An oxide film 126 is formed to extend on n⁺ region 124 in one p region 123, p region 123, an exposed portion of reverse breakdown voltage holding layer 122 between the two p regions 123, the other p region 123, and n⁺ region 124 in the other p region 123′ On oxide film 126, gate electrode 110 is formed. Further, source electrodes 111 are formed on n⁺ regions 124 and p⁺ regions 125. On source electrodes 111, upper source electrodes 127 are formed.

The maximum value of the nitrogen atom concentration is 1×10²¹ cm⁻³ or greater in a region distant away by not more than 10 nm from an interface between oxide film 126 and each of n⁺ regions 124, p⁺ regions 125, p regions 123 and reverse breakdown voltage holding layer 122, which serve as semiconductor layers. This achieves improved mobility particularly in a channel region below oxide film 126 (a contact portion of each p region 123 with oxide film 126 between each of n⁺ regions 124 and reverse breakdown voltage holding layer 122).

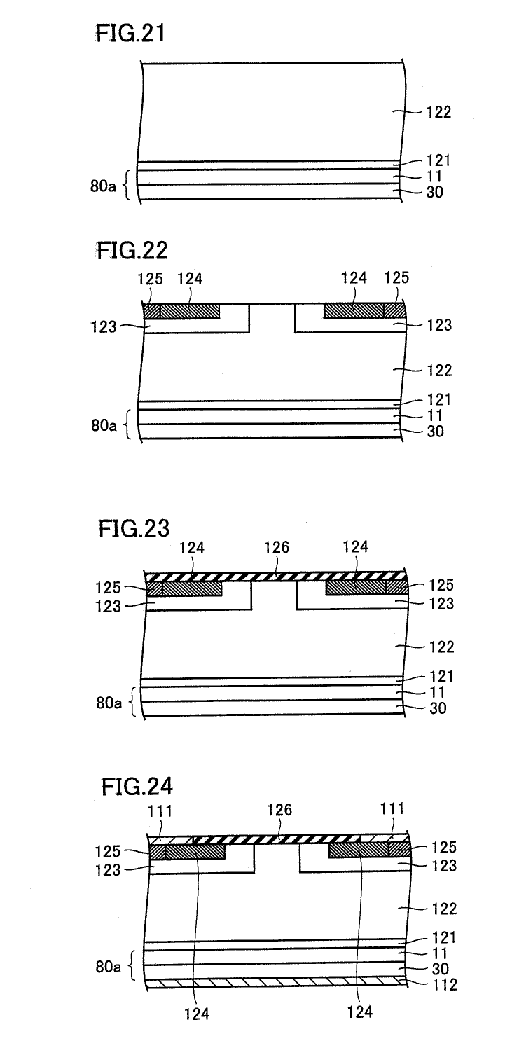

The following describes a method for manufacturing a semiconductor device 100. It should be noted that FIG. 21-FIG. 24 show steps only in the vicinity of SiC substrate 11 of SiC substrates 11-19 (FIG. 1), but the same steps are performed also in the vicinity of each of SiC substrates 12-19.

First, in a substrate preparing step (step S110: FIG. 20), semiconductor substrate 80a (FIG. 1 and FIG. 2) is prepared. Semiconductor substrate 80a has n type conductivity.

Referring to FIG. 21, in an epitaxial layer forming step (step S120: FIG. 20), buffer layer 121 and reverse breakdown voltage holding layer 122 are formed as follows.

First, buffer layer 121 is formed on SiC substrate 11 of semiconductor substrate 80a. Buffer layer 121 is made of silicon carbide of n type conductivity, and is an epitaxial layer having a thickness of 0.5 μm, for example. Buffer layer 121 has a conductive impurity at a concentration of, for example, 5×10¹⁷ cm⁻³.

Next, reverse breakdown voltage holding layer 122 is formed on buffer layer 121. Specifically, a layer made of silicon carbide of n type conductivity is formed using an epitaxial growth method. Reverse breakdown voltage holding layer 122 has a thickness of, for example, 10 μm. Further, reverse breakdown voltage holding layer 122 includes an impurity of n type conductivity at a concentration of, for example, 5×10¹⁵ cm⁻³.

Referring to FIG. 22, an implantation step (step S130: FIG. 20) is performed to form p regions 123, n⁺ regions 124, and p⁺ regions 125 as follows.

First, an impurity of p type conductivity is selectively implanted into portions of reverse breakdown voltage holding layer 122, thereby forming p regions 123. Then, a conductive impurity of n type is selectively implanted to predetermined regions to form n⁺ regions 124, and a conductive impurity of p type is selectively implanted into predetermined regions to form p⁺ regions 125. It should be noted that such selective implantation of the impurities is performed using a mask formed of, for example, an oxide film.

After such an implantation step, an activation annealing process is performed. For example, the annealing is performed in argon atmosphere at a heating temperature of 1700° C. for 30 minutes.

Referring to FIG. 23, a gate insulating film forming step (step S140: FIG. 20) is performed. Specifically, oxide film 126 is formed to cover reverse breakdown voltage holding layer 122, p regions 123, n⁺ regions 124, and p⁺ regions 125. Oxide film 126 may be formed through dry oxidation (thermal oxidation). Conditions for the dry oxidation are, for example, as follows: the heating temperature is 1200° C. and the heating time is 30 minutes.

Thereafter, a nitrogen annealing step (step S150) is performed. Specifically, annealing process is performed in nitrogen monoxide (NO) atmosphere. Conditions for this process are, for example, as follows: the heating temperature is 1100° C. and the heating time is 120 minutes. As a result, nitrogen atoms are introduced into a vicinity of the interface between oxide film 126 and each of reverse breakdown voltage holding layer 122, p regions 123, n⁺ regions 124, and p⁺ regions 125.

It should be noted that after the annealing step using nitrogen monoxide, additional annealing process may be performed using argon (Ar) gas, which is an inert gas. Conditions for this process are, for example, as follows: the heating temperature is 1100° C. and the heating time is 60 minutes.

Referring to FIG. 24, an electrode forming step (step S160: FIG. 20) is performed to form source electrodes 111 and drain electrode 112 in the following manner.

First, a resist film having a pattern is formed on oxide film 126, using a photolithography method. Using the resist film as a mask, portions above n⁺ regions 124 and p⁺ regions 125 in oxide film 126 are removed by etching. In this way, openings are formed in oxide film 126. Next, in each of the openings, a conductive film is formed in contact with each of n⁺ regions 124 and p⁺ regions 125. Then, the resist film is removed, thus removing the conductive film's portions located on the resist film (lift-off). This conductive film may be a metal film, for example, may be made of nickel (Ni). As a result of the lift-off, source electrodes 111 are formed.

It should be noted that on this occasion, heat treatment for alloying is preferably performed. For example, the heat treatment is performed in atmosphere of argon (Ar) gas, which is an inert gas, at a heating temperature of 950° C. for two minutes.

Referring to FIG. 19 again, upper source electrodes 127 are formed on source electrodes 111. Further, drain electrode 112 is formed on the backside surface of semiconductor substrate 80a. Further, gate electrode 110 is formed on oxide film 126. In this way, semiconductor device 100 is obtained.

It should be noted that a configuration may be employed in which conductive types are opposite to those in the present embodiment. Namely, a configuration may be employed in which p type and n type are replaced with each other.

Further, the DiMOSFET of vertical type has been exemplified, but another semiconductor device may be manufactured using the semiconductor substrate of the present invention. For example, a RESURF-JFET (Reduced Surface Field-Junction Field Effect Transistor) or a Schottky diode may be manufactured.

### APPENDIX 1

The semiconductor substrate of the present invention is manufactured in the following method for manufacturing.

A combined substrate is provided which has a supporting portion and first and second silicon carbide substrates. The first silicon carbide substrate has a first backside surface connected to the supporting portion, a first front-side surface opposite to the first backside surface, and a first side surface connecting the first backside surface and the first front-side surface. The second silicon carbide substrate has a second backside surface connected to the supporting portion, a second front-side surface opposite to the second backside surface, and a second side surface connecting the second backside surface and the second front-side surface. The second side surface is disposed such that a gap having an opening between the first and second front-side surfaces is formed between the first side surface and the second side surface. A silicon connecting portion is formed to connect the first and second side surfaces so as to close the opening, by introducing melted silicon from the opening to the gap. A silicon carbide connecting portion is formed to connect the first and second side surfaces so as to close the opening, by carbonizing the silicon connecting portion.

### APPENDIX 2

The semiconductor device of the present invention is fabricated using a semiconductor substrate fabricated using the following method for manufacturing.

A combined substrate is provided which has a supporting portion and first and second silicon carbide substrates. The first silicon carbide substrate has a first backside surface connected to the supporting portion, a first front-side surface opposite to the first backside surface, and a first side surface connecting the first backside surface and the first front-side surface. The second silicon carbide substrate has a second backside surface connected to the supporting portion, a second front-side surface opposite to the second backside surface, and a second side surface connecting the second backside surface and the second front-side surface. The second side surface is disposed such that a gap having an opening between the first and second front-side surfaces is formed between the first side surface and the second side surface. A silicon connecting portion is formed to connect the first and second side surfaces so as to close the opening, by introducing melted silicon from the opening to the gap. A silicon carbide connecting portion is formed to connect the first and second side surfaces so as to close the opening, by carbonizing the silicon connecting portion.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### INDUSTRIAL APPLICABILITY

A method for manufacturing a semiconductor substrate in the present invention is advantageously applicable particularly to a method for manufacturing a semiconductor substrate including a portion made of silicon carbide having a single-crystal structure.

### DESCRIPTION OF THE REFERENCE SIGNS

BDa: silicon carbide connecting portion; BDp: silicon connecting portion; 10: SiC substrate group; 10a: supported portion; 11: SiC substrate (first silicon carbide substrate); 12: SiC substrate (second silicon carbide substrate); 13-19: SiC substrate; 20, 20p: solid source material; 21: Si material; 22: Si melt; 30, 30p: supporting portion; 70: silicon layer; 72: carbonized layer; 80a: semiconductor substrate; 80P: combined substrate; 81: first heating member; 82: second heating member; 100: semiconductor device.

1. A method for manufacturing a semiconductor substrate, comprising the steps of:
preparing a combined substrate having a supporting portion and first and second silicon carbide substrates, said first silicon carbide substrate having a first backside surface connected to said supporting portion, a first front-side surface opposite to said first backside surface, and a first side surface connecting said first backside surface and said first front-side surface, said second silicon carbide substrate having a second backside surface connected to said supporting portion, a second front-side surface opposite to said second backside surface, and a second side surface connecting said second backside surface and said second front-side surface, said second side surface being disposed such that a gap having an opening between said first and second front-side surfaces is formed between said first side surface and said second side surface;
forming a silicon connecting portion for connecting said first and second side surfaces so as to close said opening by introducing melted silicon from said opening to said gap; and
forming a silicon carbide connecting portion for connecting said first and second side surfaces so as to close said opening by carbonizing said silicon connecting portion.

2. The method for manufacturing the semiconductor substrate according to claim 1, wherein the step of forming said silicon carbide connecting portion includes the step of supplying said silicon connecting portion with a gas containing carbon element.

3. The method for manufacturing the semiconductor substrate according to claim 1, further comprising the step of exposing said first and second front-side surfaces after the step of forming said silicon carbide connecting portion.

4. The method for manufacturing the semiconductor substrate according to claim 1, further comprising the step of performing polishing over said first and second front-side surfaces after the step of forming said silicon connecting portion and before the step of forming said silicon carbide connecting portion.

5. The method for manufacturing the semiconductor substrate according to claim 1, wherein the step of forming said silicon connecting portion includes the steps of:
providing a silicon layer for covering said gap over said opening; and
melting said silicon layer.

6. The method for manufacturing the semiconductor substrate according to claim 5, wherein the step of providing said silicon layer is performed using any of a chemical vapor deposition method, an evaporation method, and a sputtering method.

7. The method for manufacturing the semiconductor substrate according to claim 1, wherein the step of forming said silicon connecting portion includes the steps of:
preparing melted silicon; and
immersing said opening into said melted silicon.

8. The method for manufacturing the semiconductor substrate according to claim 1, wherein said supporting portion is made of silicon carbide.
